(19) United States
(12) Patent Application Publication
(10) Pub. No.: US 2024/0204479 A1
(43) Pub. Date: Jun. 20, 2024

(54) VERTICAL CAVITY SURFACE EMITTING LASER (VCSEL), LASER SENSOR AND METHOD OF PRODUCING A VCSEL

(71) Applicant: TRUMPF Photonic Components GmbH, Ulm (DE)

(72) Inventors: Ulrich Weichmann, Aachen (DE); Holger Joachim Moench, BM Vaals (NL)

(21) Appl. No.: 18/589,469

(22) Filed: Feb. 28, 2024

Related U.S. Application Data
(63) Continuation of application No. PCT/EP2022/073842, filed on Aug. 26, 2022.

(30) Foreign Application Priority Data
Aug. 30, 2021 (DE) 10 2021 122 386.5

(51) Int. Cl. H01S 5/026; H01S 5/183; H01S 5/30; H01S 5/34

(52) U.S. Cl. CPC H01S 5/0262; H01S 5/18311; H01S 5/3054; H01S 5/3416; H01S 5/18305

(57) ABSTRACT

A vertical cavity surface emitting laser includes an optical resonator, a photodiode, and an electrical contact arrangement. The optical resonator includes a semiconductor multilayer stack. The semiconductor multilayer stack includes, in a direction of growth of the multilayer stack, a first distributed Bragg reflector, a second distributed Bragg reflector, and an active region for laser emission arranged between the first distributed Bragg reflector and second distributed Bragg reflector. The electrical contact arrangement is arranged to electrically pump the optical resonator and to electrically contact the photodiode. A reflectivity of the second distributed Bragg reflectoris higher than a reflectivity of the first distributed Bragg reflector. The photodiode has an absorbing region arranged in the second distributed Bragg reflector. A tunnel junction is arranged between the photodiode and the active region.

### CROSS REFERENCE TO RELATED APPLICATIONS

This application is a continuation of International Application No. PCT/EP2022/073842 (WO 2023/031058 A1) filed on Aug. 26, 2022, and claims benefit to German Patent Application No. DE 10 2021 122 386.5, filed on Aug. 30, 2021. The aforementioned applications are hereby incorporated by reference herein.

### FIELD

Embodiments of the present invention relate to a Vertical Cavity Surface Emitting Laser (VCSEL) with integrated photodiode. Embodiments of the present invention further relate to an optical sensor comprising such a VCSEL and a method of producing a VCSEL.

### BACKGROUND

VCSELs with integrated photodiodes, commonly briefly referred to as ViPs, may be used as miniaturized sensors for the measurement of e.g. distances, displacements, velocities, particle densities, etc. All these measurements may be based on the principle of self-mixing interference (SMI). Optical sensors of this type might be simple enough to be easily integrated in mobile devices, e.g. in mobile phones.

U.S. Pat. No. 8,467,428 B2 discloses a ViP which emits laser radiation towards the front-side, i.e. towards the side facing away from the substrate. The photodiode is integrated in the bottom distributed Bragg reflector in vicinity of the substrate. This ViP has a third pn-junction between the photodiode and the active region of the ViP in addition to the pn-junctions of the photodiode and the laser diode.

WO 2019/141545 A1 discloses a ViP which comprises a photodiode integrated in the top DBR. The ViP has two intracavity contacts making the ViP a 4 terminal device which requires a more complex epitaxial structure and processing. The ViP comprises a highly doped p-contact inside the optical resonator which needs to be as thin as possible requiring to work with selective etching using an etch stop layer.

U.S. Pat. No. 7,184,454 B2 discloses a monolithically formed laser and photodiode. The monolithically formed laser and photodiode includes a VCSEL that includes a first pn-junction. A tunnel diode is connected to the VCSEL both physically and electronically through a waver fabrication process. A photodiode is connected to the tunnel diode. The photodiode is connected to a tunnel diode by physical and electronic connections. The tunnel diode and photodiode may share some common layers. In this ViP, the optical resonator of the VCSEL and the photodiode are separate blocks of the device, i.e. the photodiode is not integrated in the optical resonator.

The above mentioned known ViPs have disadvantages in terms of at least one of capacitance, additional bias voltage, decreased design flexibility, more complex epitaxial structure and processing, and require a more complex ASIC (driver and amplifier) for operation.

Therefore, there is a need for an improved VCSEL with integrated photodiode.

### SUMMARY

Embodiments of the present invention provide a vertical cavity surface emitting laser. The vertical cavity surface emitting laser includes an optical resonator, a photodiode, and an electrical contact arrangement. The optical resonator includes a semiconductor multilayer stack. The semiconductor multilayer stack includes, in a direction of growth of the multilayer stack, a first distributed Bragg reflector, a second distributed Bragg reflector, and an active region for laser emission arranged between the first distributed Bragg reflector and second distributed Bragg reflector. The electrical contact arrangement is arranged to electrically pump the optical resonator and to electrically contact the photodiode. A reflectivity of the second distributed Bragg reflectoris higher than a reflectivity of the first distributed Bragg reflector. The photodiode has an absorbing region arranged in the second distributed Bragg reflector. A tunnel junction is arranged between the photodiode and the active region.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows a sketch of a Vertical Cavity Surface Emitting Laser with integrated photodiode according to a first embodiment;

FIG. 2 shows a Vertical Cavity Surface Emitting Laser with integrated photodiode according to a second embodiment;

FIG. 3 shows an electrical circuit diagram of the Vertical Cavity Surface Emitting Laser with integrated photodiode of FIG. 1 and FIG. 2;

FIG. 4 shows a sketch of a laser sensor according to some embodiments; and

FIG. 5 shows a flow diagram of a method of producing a Vertical Cavity Surface Emitting Laser according to some embodiments.

### DETAILED DESCRIPTION

Embodiments of the present invention provide a VCSEL which overcomes at least a part of the drawbacks of the known ViPs.

Embodiments of the present invention provide a VCSEL with integrated photodiode which has reduced capacitance and/or requires lower bias voltage.

Embodiments of the present invention provide a VCSEL with integrated photodiode which poses less design limitations on the epitaxial structure of the ViP.

Embodiments of the present invention provide a laser sensor comprising an improved VCSEL with integrated photodiode.

Embodiments of the present invention provide a method of producing an improved VCSEL with integrated photodiode.

According to an aspect of the invention, a Vertical Cavity Surface Emitting Laser (VCSEL) is provided, comprising an optical resonator, a photodiode, and an electrical contact arrangement, the optical resonator comprising a semiconductor multilayer stack, the multilayer stack comprising, in direction of growth of the semiconductor multilayer stack, a first distributed Bragg reflector and a second distributed Bragg reflector and an active region for laser emission, which is arranged between the first and second distributed Bragg reflectors, wherein the electrical contact arrangement is arranged to electrically pump the optical resonator and to electrically contact the photodiode, wherein the second distributed Bragg reflector has a higher reflectivity than the first distributed Bragg reflector, wherein the photodiode has an absorbing region arranged in the second distributed Bragg reflector, and wherein a tunnel junction is arranged between the photodiode and the active region.

The VCSEL according to embodiments of the invention has the photodiode arranged, monolithically integrated in the front-side (top or upper) distributed Bragg reflector (in the following, a distributed Bragg reflector is briefly referred to as DBR). Laser emission occurs through the back-side (bottom or lower) DBR. A back-side emitting laser has some advantages over front-side emitting lasers, like integrated optics and smaller contact areas.

Arranging the photodiode in the DBR on the non-emission side of the VCSEL has several advantages. When, in contrast, the photodiode is integrated in the outcoupling DBR of a bottom emitting VCSEL, the outcoupling DBR, comprising n-contact, photodiode and pn-junction from photodiode to laser diode, needs to consist of about only half the DBR pairs as compared to front-side emission, in order to allow higher emission. This disadvantage is overcome by the VCSEL according to embodiments of the invention. The VCSEL according to embodiments of the invention thus provides higher flexibility to position the individual groups of the layer stack independent from each other and in an ideal position.

A further advantage of the arrangement of the photodiode in the upper DBR on the non-emission side is that the photodiode is less sensitive to environmental light and therefore additional noise and non-linearities in an SMI measurement are reduced. The risk of saturation of the photodiode due to a strong environmental background is avoided or at least reduced.

Further, arranging the photodiode in the upper region of the epitaxial multilayer stack has the advantage that the photodiode can be easily reached by e.g. a trench etch or an implantation to reduce the capacitance and background absorption. In contrast, when the photodiode is arranged in lower regions of the epitaxial stack, it is more difficult to reach the photodiode by e.g. a trench etch or an implantation.

Further, the VCSEL according to embodiments of the invention comprises a tunnel junction in the multilayer stack between the photodiode and the active region. The main advantage of the tunnel junction is that the voltage drop across the tunnel junction is significantly lower than the voltage drop across a “normal” pn-junction. The tunnel junction not only allows to arrange the photodiode, seen in growth direction of the multilayer stack, beyond the active region in the multilayer stack, but also keeps the DBR design and contacting strategy unchanged. In particular, it allows for a three-terminal device with one intracavity contact only.

In an embodiment, the second distributed Bragg reflector may have an outer first part and an inner or intermediate second part, wherein the absorbing region of the photodiode is arranged between the first part and the second part, wherein the outer first part is a p-doped region of the semiconductor multilayer stack, and the inner second part is an n-doped region of the semiconductor multilayer stack.

Such a configuration is advantageous, because the photodiode may have a p-i-n structure (seen in direction opposite to the growth direction of the multilayer stack), with i denoting the absorbing region of the photodiode, so that the photodiode may be electrically contacted via an intracavity n-contact and an outer p-contact. An intracavity n-contact has the advantage over an intracavity p-contact that the latter needs to be as thin as possible requiring to work with selective etching using an etching stop layer. Such a more complex processing is not necessary with the present embodiment. When the intracavity contact is realized in the n-conducting region, the further advantage is that undesired absorption is low and lateral conductivity is high.

In a further embodiment, the second distributed Bragg reflector may have an inner third part which is a p-doped region, wherein the tunnel junction is arranged between the second part and the third part of the second distributed Bragg reflector.

It is advantageous here that the tunnel junction removes the parasitic diode between the second part and the third part of the second DBR, and thus the parasitic diode between the photodiode in the upper region of the multilayer stack and the laser diode (active region) in the lower region of the multilayer stack. The tunnel junction may be realized by high or ultra-high doped and very thin layers on both sides of the polarity change between the second and third part of the second DBR.

In a further embodiment, a diameter or width of the absorbing region may be smaller than a diameter or width of the active region.

This embodiment is rendered possible by arranging the photodiode in the upper region of the multilayer stack. The diameter or width of the absorbing region of the photodiode can be easily made by e.g. a mesa etch of the multilayer stack in the region of the photodiode or by an ion implantation. A small as possible photodiode diameter or width has the advantageous effect of low capacitance of the photodiode. Furthermore, less light from spontaneous emission (undirected) is received by the photodiode.

In a further embodiment, the absorbing region may have a diameter or width of less than 15 μm, preferably less than 10 μm, preferably in a range from 4 μm to 8 μm.

An absorbing region with a diameter or width in the given ranges would be large enough to sufficiently capture light, but is small enough to reduce capacitance. If gallium arsenide (GaAs) is used as the material system for the multilayer stack, a 4 μm-8 μm diameter photodiode is sufficient as the beam divergence in GaAs is small. The smaller the photodiode diameter can be made, the less light from spontaneous emission (undirected) is received by the photodiode and therefore a background not useful for SMI sensing is reduced. Furthermore, the capacity can be very small which has advantages in high frequency signal processing.

In a further embodiment, the electrical contact arrangement may have an intracavity contact, which forms a common anode of the photodiode and for pumping the active region. Preferably, the intracavity contact is an n-contact.

When the photodiode and the laser diode (active region) share a common anode, this allows for a less complex and less noisier ASIC (driver plus amplifier) in comparison to a design where the intracavity contact needs to be the cathode for the photodiode, but the anode for the laser diode. In the latter case, a galvanic separation in the ASIC is required, not allowing any common ground solutions. An intracavity n-contact contacting an n-doped layer, in particular a thick n-buffer layer, has the advantage that lateral conductivity is high and thus injecting carriers from the lateral side works well.

In an embodiment, the electrical contact arrangement may be arranged to operate the photodiode and the tunnel junction with reverse bias and the active region with forward bias.

Operating the photodiode and the tunnel junction with reverse bias is optimal for proper functioning of these components. An operation of the active region or laser diode with forward-bias and the photodiode and the tunnel junction in reverse bias may be advantageously realized in a three-terminal design which is rendered possible due to the design concept of the VCSEL according to embodiments of the invention. Thus, a more complex four-terminal design is not needed according to embodiments of the invention.

Preferably, the tunnel junction may be arranged in or next to a node of a standing wave pattern of the laser emission in the optical resonator. This arrangement of the tunnel junction advantageously reduces absorption by the tunnel junction, considering the high doping level of the layers of the tunnel junction.

In a further embodiment, the tunnel junction may have a high or ultra-high doped n⁻⁻-layer, which may be doped with Tellurium, and/or in another embodiment, the tunnel junction may have a high or ultra-high doped p⁺⁺-layer, which may be doped with carbon.

Doping concentrations of the n⁻⁻-layer may be as high as 8×1018 cm⁻³ or even higher and of the p⁺⁺-layer as high as 10¹⁹ cm⁻³ or even higher. Thicknesses of the tunnel junction layers may be less than 20 nm.

The other n-doped layers of the semiconductor multilayer stack may be doped with silicon (Si).

In a further embodiment, the optical resonator may comprise an oxide aperture or ion implantation next to or in vicinity of the absorbing region of the photodiode.

An oxide aperture or ion implantation next to or in the vicinity of the absorbing region of the photodiode may advantageously reduce the effective photodiode diameter which reduces spontaneous emission reaching the photodiode and reduces background light reaching the photodiode which is not useful for SMI sensing purposes. It is to be noted that the oxide aperture or ion implantation next to or in vicinity of the absorbing region of the photodiode is not necessarily the only oxide aperture or ion implantation in the semiconductor multilayer stack. One or more further oxide apertures or ion implantations for current and/or optical confinement may be provided in the semiconductor multilayer stack, e.g. in vicinity of the active region.

In a further embodiment, the VCSEL may further comprise a substrate, arranged on a back-side of the first DBR, wherein the substrate preferably has an optical structure, which may be arranged on a surface of the substrate which is opposite to the surface on which the multilayer stack is grown.

In this embodiment, a bottom emitting VCSEL with integrated photodiode and integrated optics for e.g. beam shaping may be advantageously realized. The optical structure may be any of one or more diverging or converging lenses, a diffusing structure, a diffracting optical structure, e.g. a grating, etc.

In embodiments, the substrate can be thinned to 150 μm or even 180 μm to reduce size and absorption, for example when the optical structure is made to provide a simple beam deflection. In such a case, the optical structure may comprise a plurality of micro lenses or micro prismatic elements, for example.

In other embodiments, e.g. for focusing or collimation, a larger useful lens diameter may be helpful and then the substrate may be as thick as possible, e.g. the typical original 625 μm.

It is also possible to remove the substrate completely, and have a separate or no optics in other embodiments.

Preferably, the VCSEL according to embodiments of the invention is a three-terminal device. Further, the VCSEL according to embodiments of the invention preferably is a bottom (or back-side) emitting ViP.

The multilayer structure or stack of the VCSEL according to embodiments of the invention may be characterized by a sequence of p- and n-doped and intrinsic regions, e.g. in the order p-i-n-n⁺⁺-p⁺⁺-p-i-n. “Intrinsic” here means not intentionally doped or not comprising a significant amount of foreign atoms, and does not necessarily mean free of any foreign atoms.

The substrate, if present, may be an n-doped semiconductor substrate, or a semi-insulating semiconductor substrate.

The electrical contact arrangement may have an n-contact on the outer side (back-side) of the substrate. Alternatively, an n-contact can be made on the top-side of the substrate, either in the substrate itself or in an n-doped buffer layer. In the latter case, the substrate could be of semi-insulated type in order to minimize absorption.

According to a second aspect of the invention, a laser sensor is provided, comprising a Vertical Cavity Surface Emitting Laser according to the first aspect, wherein the laser sensor is at least one of a displacement sensor, a proximity sensor, a distance sensor, a particle sensor, a contactless user interface sensor. The sensor especially may be a sensor which uses SMI for detection or measuring.

According to a third aspect, a method of producing a Vertical Cavity Surface Emitting Laser having an optical resonator, a photodiode, and an electrical contact arrangement is provided, the method comprising:
arranging, by growing a semiconductor multilayer stack, a first distributed Bragg reflector, an active region for laser emission, and a second distributed Bragg reflector, the active region arranged between the first and second distributed Bragg reflectors, providing the second distributed Bragg reflector with a higher reflectivity than the first distributed Bragg reflector, arranging an absorbing region of the photodiode in the second distributed Bragg reflector, and arranging a tunnel junction between the photodiode and the active region, and
electrically contacting the optical resonator for pumping the active region and electrically contacting the photodiode.

It shall be understood that the VCSEL described herein and the laser sensor and the method of producing the VCSEL have similar and/or identical embodiments, in particular as defined in the claims. Further advantageous embodiments are defined below.

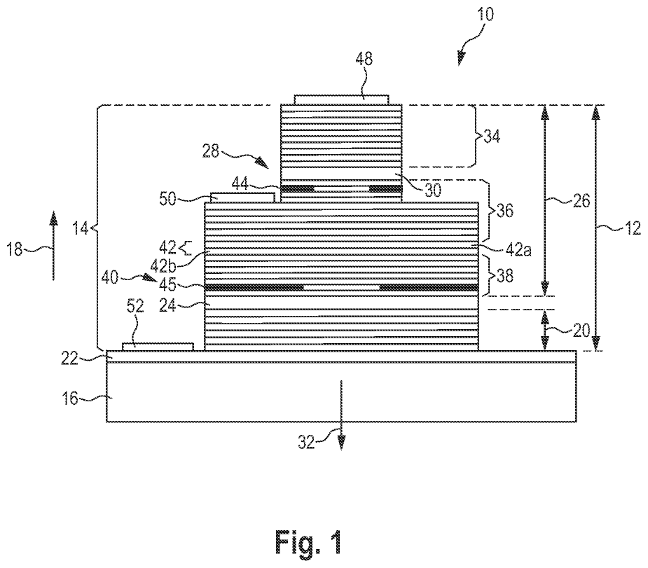

With reference to FIG. 1, a first embodiment of a VCSEL 10 will be described.

The VCSEL 10 comprises an optical resonator 12, also referred to as laser cavity. The optical resonator 12 comprises a semiconductor multilayer stack 14, comprising a multitude of semiconductor layers which are only schematically indicated in FIG. 1. The thicknesses of the layers shown in the drawings are not to scale and not limiting, and the number of layers shown is not limiting, either. The semiconductor multilayer stack 14 may comprise semiconductor layers of the material system AlGaAs/GaAs or InGaAs/GaAs, for example. Other material systems are conceivable as well. The semiconductor layers of the semiconductor multilayer stack 14 may be grown on a substrate 16 by conventional epitaxial methods. An arrow 18 indicates the growth direction of the multi layer stack 14.

The optical resonator 12 includes a first distributed Bragg reflector (DBR) 20. The first DBR 20 may be arranged immediately on the substrate 16 or, as shown in FIG. 1, on a buffer layer 22 arranged on the substrate 16. The buffer layer 22 will be further described later.

The first DBR 20 may comprise a plurality of pairs of semiconductor layers, wherein each pair has a low refractive index layer and a high refractive index layer.

The semiconductor multilayer stack 14 further comprises an active region 24. The active region 24 may comprise one or more quantum wells as known in the art. The active region 24 generates laser emission when the active region 24 is electrically pumped.

The semiconductor multilayer stack 14 further comprises a second DBR 26. The active region 24 is arranged between the first DBR 20 and the second DBR 26. The second DBR 26 may comprise a plurality of pairs of semiconductor layers, each pair comprising a low refractive index layer and a high refractive index layer.

The second DBR 26 is also referred to as the front-side or upper DBR, and the first DBR 20 is also referred to as the back-side or lower DBR.

Monolithically integrated or embedded in the second DBR 26 is a photodiode 28 which comprises an absorbing region 30. The semiconductor layer or semiconductor layers of the absorbing region 30 may be made of the same material system as the quantum well layers of the active region 24. The absorbing region 30 may comprise one or more layers.

The second DBR 26 and the first DBR 20 are made such that the reflectivity of the second DBR 26 is higher than the reflectivity of the first DBR 20. For example, the reflectivity of the second DBR 26 may be higher than 99%, while the reflectivity of the first DBR 20 may be lower than 99%, e.g. about 98%. When the optical resonator 12 is electrically pumped, laser light generated in the active region 24 will be emitted through the first DBR 20 and through the substrate 16. The substrate 16 may be transmissive for laser wavelengths >940 nm, for example. As laser emission is coupled out of the resonator 12 through the first DBR 20, i.e. through the DBR on the substrate side, the VCSEL 10 is a bottom or back-side emitter. In FIG. 1, the laser emission is illustrated by an arrow 32.

The photodiode 28 is arranged to receive and absorb laser light generated by the active region 24. When the VCSEL 10 is used in self-mixing interference (SMI) measurements, laser light reflected or scattered back from an object in the environment of the VCSEL 10 into the optical resonator 12 interferes with the standing wave in the optical resonator 12 which leads to light intensity variations in the optical resonator 12 which can be detected by the photodiode 28.

The second DBR 26 includes three parts in the present embodiment, namely an outer or top first part 34, an inner or intermediate second part 36, and an inner third part 38. The outer first part 34 preferably is a p-doped region of the semiconductor multilayer stack 14. The inner or intermediate second part 36 preferably is an n-doped region of the semiconductor multilayer stack 14. The inner third part 38 of the second DBR 26 preferably is an n-doped region of the semiconductor multilayer stack 14. The photodiode 28 is built up by the outer first part 34 of the second DBR 26, the absorbing region 30, and the inner or intermediate second part 36 of the second DBR 26. The photodiode 28 thus is a p-i-n photodiode. The inner third part 38 of the second DBR 26, which preferably is a p-doped region of the semiconductor multilayer stack 14, the active region 24 and the first DBR 20, which preferably is an n-doped region of the semiconductor multilayer stack 14, build up the laser diode part 40 of the VCSEL 10. Thus, a third pn-junction would be present in the multilayer stack 14, namely between the photodiode 28 and the laser diode 40. Such an additional “normal” pn-junction causes a relatively high voltage drop across the pn-junction. A high voltage drop across a “normal” pn-junction requires an additional bias voltage of about 0.6 V to establish a current through the pn-junction. This additional bias voltage times the current is an undesired waste heat increasing the temperature of the VCSEL.

Therefore, a tunnel junction or tunnel diode 42 is arranged between the p-i-n photodiode 28 and the p-i-n laser diode 40. In other words, the pn-junction between the photodiode 28 and the active region 24 is realized as a tunnel junction. The tunnel junction 42 has a high or ultra-high doped n⁻⁻-layer 42a facing the n-doped region of the inner or intermediate second part 36 of the second DBR 26, and a high or ultra-high doped p⁺⁺-layer 42b on the side facing the p-doped region of the inner third part 38 of the second DBR 26. Doping concentrations of the n⁻⁻-layer may be as high as 8×1018 cm⁻³ or even higher and of the p⁺⁺-layer as high as 10¹⁹ cm⁻³ or even higher. The tunnel junction layers 42a and 42b are very thin, e.g. have thicknesses <20 nm. On the n-side, Tellurium is preferably used as the dopant, and on the p-side of the tunnel junction, carbon may be used as dopant, because carbon is a standard p-dopant and can be incorporated at high concentration. The voltage drop across the tunnel junction 42 can be <<0.2 V, and therefore the needed additional bias voltage is much lower than in designs with a “normal” parasitic diode. The tunnel junction 42 is preferably arranged in a node of the standing wave pattern of the laser emission in the optical resonator 12 in order to keep absorption by the high doped layers of the tunnel junction 42 as low as possible.

The arrangement of the photodiode 28 in the upper part of the semiconductor multilayer stack 14 allows the absorbing region 30 of the photodiode 28 to be easily made with a reduced diameter or width which is smaller than the diameter or width of the active region, as shown in FIG. 1. A photodiode 28 with reduced diameter or width can be easily made when the photodiode 28 is arranged in the top part of the VCSEL 10, because the upper part of the semiconductor multilayer stack 14 is well accessible by a mesa etch or ion implantation. The VCSEL 10 as shown in FIG. 1 thus may be characterized by a “photodiode-mesa”. The diameter of the photodiode 28 should be large enough to capture the laser beam, but not necessarily larger. For example, for an oxide aperture (or more general: optical confinement region) diameter of the laser diode 40 of about 3 μm, a 4-5-μm photodiode absorbing region 30 would be sufficient, in particular for the material system GaAs, in which the beam divergence is small. The smaller the diameter of the absorbing region 30 can be made, the less light from spontaneous emission (undirected) is received by the photodiode 28 and therefore the background which is not useful for SMI sensing is reduced. Furthermore, a small diameter photodiode helps to keep the capacity small, which is advantageous in high frequency signal processing. The diameter or width of the absorbing region 30 may be further reduced by an oxide aperture 44. It is to be noted that a further oxide aperture 45 may be arranged as shown in the inner third part 38 of the second DBR 26 or (not shown) in the first DBR 20 for current and/or optical confinement in the laser diode part 40. The widths of oxide apertures 44 and 45 as shown in the drawings is only schematic and not to scale.

The VCSEL 10 further comprises an electrical contact arrangement. The electrical contact arrangement may comprise a first contact 48 on top of the second DBR 26. The first contact 48 preferably is a p-contact. The uppermost layer of the second DBR 26 preferably is a highly doped p-layer, because a low sheet resistance metal alloy contact can be realized in this case. The area of such a contact on top of the mesa is rather limited and low resistance is thus beneficial.

The electrical contact arrangement may further comprise an intracavity contact 50. The intracavity contact 50 is preferably realized in the n-conducting region of the inner or intermediate second part 36 of the second DBR 26. The advantage of an arrangement of the intracavity contact 50 in the n-conducting region is that absorption is low and lateral conductivity is high.

The electrical contact arrangement further comprises a third electrical contact 52. The electrical contact 52 is arranged in the shown embodiment on the top-side of the substrate 16, here on or in the buffer layer 22 which preferably is n-doped. In this case, the substrate 16 may be of semi-insulating type in order to minimize absorption. Alternatively, the electrical contact 52 may be arranged on the top-side of the substrate 16 without buffer layer 22. In this case, the substrate 16 preferably is of n-conducting type. Driving current for pumping the active region 24 flows between contacts 50 and 52. Photocurrent flows between 50 and 48.

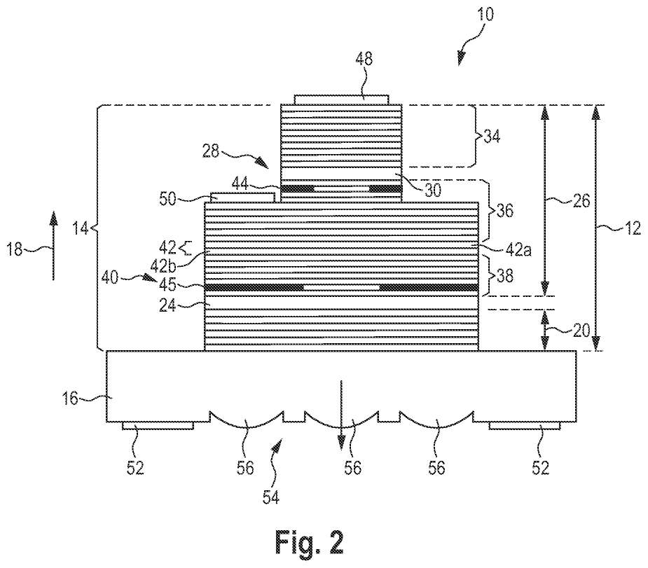

FIG. 2 shows an embodiment of the VCSEL 10, which is modified with respect to the VCSEL 10 in FIG. 1. In the following, only the differences between the VCSEL 10 in FIG. 2 and the VCSEL in FIG. 1 will be described. If not indicated otherwise, the description of the VCSEL 10 in FIG. 1 also applies to the VCSEL 10 in FIG. 2. For same or similar elements of the VCSEL 10 in FIG. 2, the same reference numerals as in FIG. 1 are used.

One difference of the VCSEL 10 in FIG. 2 with respect to the VCSEL 10 in FIG. 1 is that the third electrical contact 52 of the electrical contact arrangement is arranged on the back-side of the substrate 16. The electrical contact 52 may be made as a large ring contact. The substrate 16 needs to be of the n-conducting type in this case.

A further difference between the VCSEL 10 in FIG. 2 and the VCSEL 10 in FIG. 1 is that the substrate 16 comprises an optical structure 54 for shaping or transforming the laser light emitted through the substrate 16. The optical structure 54 is arranged on (which also includes monolithically integrated in) a surface of the substrate 16 which is opposite to a surface of the substrate, on which the multilayer stack 14 is arranged. The optical structure 54 may be of any type according to the desired optical effect the optical structure 54 shall have. In the embodiment in FIG. 2, the optical structure 54 is shown as a plurality of lenses 56. In other embodiments, the optical structure 54 may comprise a larger number of micro lenses. The optical structure may be a diffracting structure in other embodiments. The optical structure may be a diverging, converging, or collimating structure. When a simple beam deflection by the optical structure 54 is desired, the optical structure 54 may comprise a prismatic structure, for example. In this case, the substrate 16 can be thinned to a thickness below 200 μm, e.g. 150 μm or even 100 μm, to reduce size and absorption by the substrate 16. In other cases, e.g. for focusing or collimation, a larger useful lens diameter may be helpful, and then the substrate should be as thick as possible, e.g. thicker than 500 μm, e.g. 625 μm, which is a typical original thickness of a substrate.

In other embodiments, it is also possible to remove the substrate 16 completely and have the optical structure 54 as a separate optics.

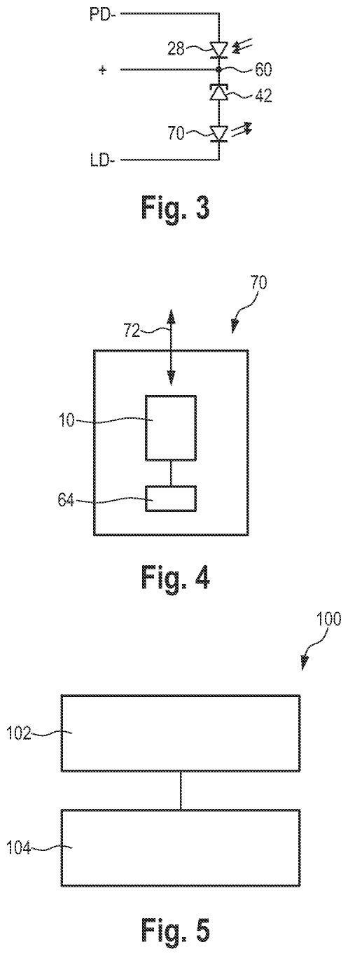

FIG. 3 shows an electrical circuit diagram illustrating the preferred type of operation of the VCSEL 10 in FIG. 1 or in FIG. 2. One advantage of the VCSEL 10 in FIGS. 1 and 2 is that the photodiode 28 and the laser diode 40 (active region) may share a common anode 60 which in this embodiment is formed by contact 50. The photodiode 28 and the tunnel junction 42 are operated with reverse bias, and the laser diode 40 (active region 24) is operated in forward bias. The common anode 60 for the photodiode 28 and the laser diode 40 can be designed in an ASIC 64 (FIG. 4) accordingly, e.g. can be shielded towards lowest noise. The design of a laser driver in the cathode part is advantageous because n-type transistors are easier to manufacture.

The VCSELs 10 in FIGS. 1 and 2 are three-terminal devices the advantage of reduced design complexity and increased design flexibility in comparison to a four-terminal device.

FIG. 4 shows a laser sensor 70 comprising the VCSEL 10 of FIG. 1 or FIG. 2 and an ASIC 64 (laser driver and amplifier). Laser light emission and laser light reception of the laser sensor 70 is illustrated by a double arrow 72. The laser sensor 70 may be any of a displacement sensor, a proximity sensor, a distance sensor, a particle sensor, a contactless user interface sensor.

The laser sensor 70 may be integrated into a mobile device like a mobile phone, a tablet, a vehicle, etc.

FIG. 5 shows a flow diagram of a method 100 of producing the VCSEL 10 of FIG. 1 or 2. In step 102, the substrate 16 is provided. The semiconductor multilayer stack 14 is epitaxially grown onto the substrate 16 to form the first DBR 20, the active region 24, the third part 38 of the second DBR 26, the tunnel junction 42, the second part 36 of the second DBR 26, the absorbing region 30 of the photodiode 28, and the first part 34 of the second DBR 26. Step 102 may also include to perform a mesa etch to form the photodiode mesa as shown in FIGS. 1 and 2. Alternatively, an ion implantation may be performed to reduce the diameter or width of the photodiode 28. The oxide aperture 44 may be realized after the mesa etch by oxidizing one or more layers of the second DBR 26 in the region of the mesa. Step 102 may also include forming the optical structure 54 in the substrate 16.

Step 104 includes electrically contacting the optical resonator 12 for pumping the active region 24 and electrically contacting the photodiode 28. Electrically contacting the optical resonator 12 includes arranging the top contact 48 on top of the second DBR 26, arranging the intracavity contact 50 on or in the n-region of the second part 36 of the second DBR 26, and arranging the electrical contract 52 on top of the buffer layer 22 or on top of the substrate 16 or on the backside of the substrate 16.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. A vertical cavity surface emitting laser, comprising:
an optical resonator,
a photodiode, and
an electrical contact arrangement,
wherein the optical resonator comprises a semiconductor multilayer stack, the semiconductor multilayer stack comprising, in a direction of growth of the multilayer stack, a first distributed Bragg reflector, a second distributed Bragg reflector, and an active region for laser emission arranged between the first distributed Bragg reflector and second distributed Bragg reflector,
wherein the electrical contact arrangement is arranged to electrically pump the optical resonator and to electrically contact the photodiode,
wherein a reflectivity of the second distributed Bragg reflectoris higher than a reflectivity of the first distributed Bragg reflector,
wherein the photodiode has an absorbing region arranged in the second distributed Bragg reflector, and
wherein a tunnel junction is arranged between the photodiode and the active region.

2. The vertical cavity surface emitting laser of claim 1, wherein the second distributed Bragg reflector has an outer first part and an inner or intermediate second part, wherein the absorbing region of the photodiode is arranged between the first part and the second part, wherein the outer first part is a p-doped region of the semiconductor multilayer stack, and the inner or intermediate second part is an n-doped region of the semiconductor multilayer stack.

3. The vertical cavity surface emitting laser of claim 2, wherein the second distributed Bragg reflector has an inner third part which is a p-doped region, wherein the tunnel junction is arranged between the second part and the third part of the second distributed Bragg reflector.

4. The vertical cavity surface emitting laser of claim 1, wherein a diameter or a width of the absorbing region is smaller than a diameter or a width of the active region.

5. The vertical cavity surface emitting laser of claim 1, wherein the absorbing region has a diameter or a width of less than 15 μm.

6. The vertical cavity surface emitting laser of claim 1, wherein the electrical contact arrangement is arranged to operate the photodiode and the tunnel junction with reverse bias and the active region with forward bias.

7. The vertical cavity surface emitting laser of claim 1, wherein the tunnel junction is arranged in or next to a node of a standing wave pattern of the laser emission in the optical resonator.

8. The vertical cavity surface emitting laser of claim 1, wherein the tunnel junction has a high or ultra-high doped n⁻⁻-layer.

9. The vertical cavity surface emitting laser of claim 8, wherein a dopant concentration in the n⁻⁻-layer is equal to or higher than 8×10¹⁸/cm³.

10. The vertical cavity surface emitting laser of claim 1, wherein the tunnel junction has a high or ultra-high doped p⁺⁺-layer.

11. The vertical cavity surface emitting laser of claim 10, wherein a dopant concentration in the p⁺⁺-layer is equal to or higher than 10¹⁹/cm³.

12. The vertical cavity surface emitting laser of claim 1, wherein the optical resonator comprises an oxide aperture or an ion implantation next to or in a vicinity of the absorbing region of the photodiode.

13. The vertical cavity surface emitting laser of claim 1, further comprising a substrate, wherein the substrate has an optical structure arranged on a surface of the substrate opposite to the multilayer stack.

14. A laser sensor, comprising a vertical cavity surface emitting laser of claim 1, wherein the laser sensor is at least one of a displacement sensor, a velocity sensor, a proximity sensor, a distance sensor, a particle sensor, or a contactless user interface sensor.

15. A method of producing a vertical cavity surface emitting laser having an optical resonator and a photodiode, the method comprising:
growing a semiconductor multilayer stack, the semiconductor multilayer stack comprising a first distributed Bragg reflector, an active region for laser emission, and a second distributed Bragg reflector, the active region arranged between the first distributed Bragg reflector and the second distributed Bragg reflector, wherein the first distributed Bragg reflector, the active region, and the second distributed Bragg reflector form the optical resonator, wherein a reflectivity of the second distributed Bragg reflector is higher than a reflectivity of the first distributed Bragg reflector,
arranging an absorbing region of the photodiode in the second distributed Bragg reflector,
arranging a tunnel junction between the photodiode and the active region,
electrically contacting the optical resonator for pumping the active region, and
electrically contacting the photodiode.
